(19) United States
(12) Patent Application Publication
(10) Pub. No.: US 2026/0096232 A1
(43) Pub. Date: Apr. 2, 2026

(54) IMAGE SENSOR

(71) Applicant: SAMSUNG ELECTRONICS CO., LTD., Suwon-si (KR)

(72) Inventors: Jinmyoung Lee, Suwon-si (KR); Sangchul Sul, Suwon-si (KR); Hyoun-Jee Ha, Suwon-si (KR)

(21) Appl. No.: 19/197,749

(22) Filed: May 2, 2025

(30) Foreign Application Priority Data
Sep. 27, 2024 (KR) 10-2024-0131579

(51) Int. Cl. H10F 39/00; H04N 25/62

(52) U.S. Cl. CPC H10F 39/80377; H04N 25/62; H10F 39/8053; H10F 39/8063; H10F 39/811

(57) ABSTRACT

An image sensor includes a substrate having a first surface and a second surface opposed to each other and having a photodiode region; a gate electrode on the photodiode region, a lower portion of the gate electrode being extended into the substrate, and an upper portion of the gate electrode disposed on the first surface of the substrate; a gate dielectric layer between the gate electrode and the substrate; a floating diffusion region on the photodiode region and on a side of the gate electrode; and a channel region extending from a lower surface of the gate dielectric layer onto a side of the floating diffusion region. The channel region includes a first channel region under the gate dielectric layer, and a second channel region under the first channel region, and the first channel region includes a two-dimensional channel layer including a transition-metal dichalcogenide (TMD) material.

### CROSS-REFERENCE TO RELATED APPLICATION(S)

This U.S. non-provisional patent application claims priority under 35 U.S.C. § 119 to Korean Patent Application No. 10-2024-0131579, filed on Sep. 27, 2024, the entire contents of which are hereby incorporated by reference.

### BACKGROUND

An image sensor converts an optical image to an electrical signal. With the development of the computer industry and the telecommunication industry, demand for the image sensor with improved performance in various fields such as a digital camera, a camcorder, a personal communication system (PCS), a gaming device, a security camera, and a medical micro-camera has increased. The image sensor may be classified into a charge coupled device (CCD) type and a complementary metal oxide semiconductor (CMOS) type. The CMOS type image sensor may also be referred to as a CMOS image sensor (CIS). The CIS includes a plurality of photodiodes (PD) two-dimensionally arranged. The photodiode serves to convert incident light to the electrical signal.

As a number of the plurality of photodiodes that are two-dimensionally arranged increases, and a size of each of pixels including the photodiodes decreases, various methods for effectively forming devices providing a pixel circuit have been proposed.

### SUMMARY

The present disclosure provides an image sensor with improved electrical characteristics.

The present disclosure also provides an image sensor in which a noise generated in a pixel may be improved.

An implementation of the present disclosure provides an image sensor including a substrate including a first surface and a second surface opposed to each other, and including a photodiode region, a gate electrode disposed on the photodiode region, a lower portion of the gate electrode being extended into the substrate, and an upper portion of the gate electrode disposed on the first surface of the substrate, a gate dielectric layer between the gate electrode and the substrate, a floating diffusion region disposed on the photodiode region, and disposed on one side of the gate electrode, and a channel region extending from a lower surface of the gate dielectric layer onto one side of the floating diffusion region, wherein the channel region includes a first channel region disposed under the gate dielectric layer, and a second channel region disposed under the first channel region, and the first channel region includes a two-dimensional channel layer including a transition-metal dichalcogenide (TMD) material.

In an implementation of the present disclosure, an image sensor includes a substrate including a first surface and a second surface opposed to each other, and including a photodiode region, a gate electrode disposed on the photodiode region, a lower portion of the gate electrode being extended into the substrate, and an upper portion of the gate electrode disposed on the first surface of the substrate, a first two-dimensional insulating layer between the gate electrode and the substrate, a floating diffusion region disposed on the photodiode region, and disposed on one side of the gate electrode, a two-dimensional channel layer extending from a lowermost surface of the first two-dimensional insulating layer onto an upper surface of the floating diffusion region, a second two-dimensional insulating layer interposed between the two-dimensional channel layer and the substrate, a two-dimensional buffer layer provided to an upper portion and a lower portion of the two-dimensional channel layer on the floating diffusion region, and a contact plug in contact with the two-dimensional buffer layer, wherein the first and second two-dimensional insulating layers include an insulating material having a two-dimensional crystal structure.

In an implementation of the present disclosure, an image sensor includes a substrate including a first surface and a second surface opposed to each other, and having a first trench recessed from the first surface of the substrate, a shallow element isolation pattern disposed in the first trench, a deep element isolation pattern disposed in the substrate, and defining a pixel region, a photodiode region provided in the substrate, a gate electrode disposed on the photodiode region, a gate dielectric layer disposed under the gate electrode, a channel region between the gate dielectric layer and the photodiode region, a floating diffusion region disposed on the photodiode region, and disposed on one side of the gate electrode, a contact plug disposed on the first surface of the substrate, and electrically connected to the floating diffusion region, a micro-lens disposed on the second surface of the substrate, and color filters interposed between the substrate and the micro-lens, wherein the channel region includes a first channel region disposed under the gate dielectric layer, and a second channel region disposed under the first channel region, the first channel region includes a two-dimensional channel layer including a TMD material, the second channel region includes a silicon channel layer, and the two-dimensional channel layer has a stepped structure, and the silicon channel layer has a structure with bends.

### BRIEF DESCRIPTION OF THE DRAWINGS

The accompanying drawings are included to provide a further understanding of the present disclosure, and are incorporated in and constitute a part of this specification. The drawings illustrate implementations of the present disclosure and, together with the description, serve to explain principles of the present disclosure. In the drawings:

FIG. 1 is a circuit diagram of a pixel of an image sensor according to an implementation of the present disclosure;

FIG. 2 is a plan view illustrating an image sensor according to an implementation of the present disclosure;

FIG. 3 is a cross-sectional view taken along line I-I′ of FIG. 2;

FIG. 4 is an enlarged diagram of portion A of FIG. 3;

FIGS. 5 and 6 are enlarged diagrams of portion A of FIG. 3, and are diagrams corresponding to another implementation of FIG. 4;

FIG. 7A is an enlarged diagram of portion A of FIG. 3, and is a diagram corresponding to another implementation of FIG. 4;

FIG. 7B is an enlarged diagram of portion B of FIG. 7A, and specifically, is a cross-sectional view taken along a direction crossing line I-I of FIG. 2;

FIG. 8 is an enlarged diagram of portion A of FIG. 3, and is a diagram corresponding to another implementation of FIG. 4;

FIG. 9 is a cross-sectional view partially illustrating an image sensor according to some implementations of the present disclosure.

### DETAILED DESCRIPTION

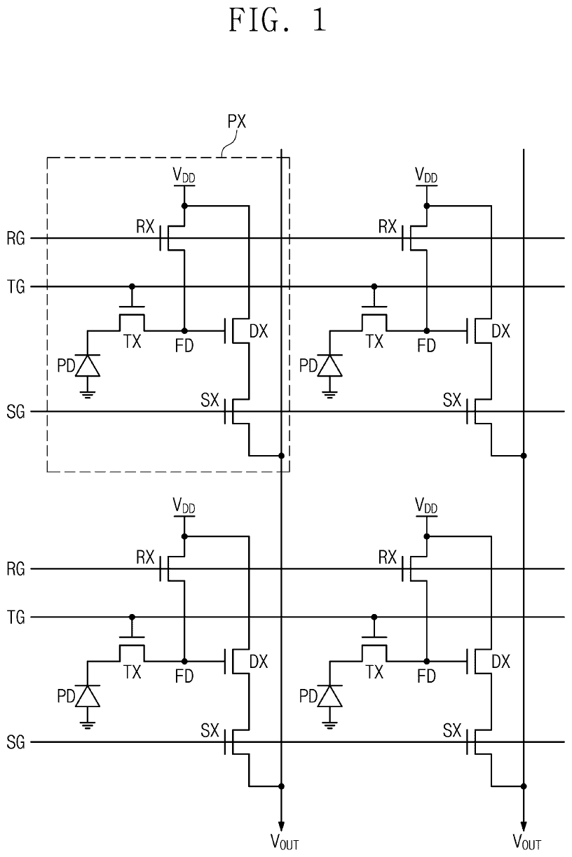

FIG. 1 is a circuit diagram of an active pixel sensor array of an image sensor according to implementations of the present disclosure.

Referring to FIG. 1, the active pixel sensor array may include a plurality of pixel regions PX, and the pixel regions PX may be arranged in a matrix shape. Each of the pixel regions PX may include a transfer transistor TX and logic transistors RX, SX and DX. The logic transistors may include a reset transistor RX, a selection transistor SX and a drive transistor DX. Each of the pixel regions PX may further include a photodiode region PD and a floating diffusion region FD.

The photodiode region PD may generate and accumulate photoelectric charges in proportion to an amount of light incident thereon from the outside. The photodiode region PD may be a photodiode including a P-type impurity region and an N-type impurity region. The floating diffusion region FD may include the N-type impurity region. The transfer transistor TX may transfer a charge generated in the photodiode region PD to the floating diffusion region FD. The floating diffusion region FD may receive the charge generated in the photodiode region PD, and may cumulatively store the charge. The drive transistor DX may be controlled depending on an amount of the photoelectric charges accumulated in the floating diffusion region FD. The floating diffusion region FD may function as a drain of the transfer transistor TX.

The reset transistor RX may periodically reset the charges accumulated in the floating diffusion region FD. A drain electrode of the reset transistor RX may be connected to the floating diffusion region FD, and a source electrode of the reset transistor RX may be connected to a power voltage VDD. When the reset transistor RX is turned on, the power voltage VDD connected to the source electrode of the reset transistor RX may be applied to the floating diffusion region FD. Accordingly, when the reset transistor RX is turned on, the charges accumulated in the floating diffusion region FD may be discharged to reset the floating diffusion region FD.

The drive transistor DX may serve as a source follower buffer amplifier. The drive transistor DX may amplify an electric potential change in the floating diffusion region FD, and may output the electric potential change to an output line Vout.

The selection transistor SX may select the pixel regions PX that are read in a row unit. When the selection transistor SX is turned on, the power voltage VDD may be applied to a drain electrode of the drive transistor DX.

FIG. 1 exemplarily illustrates a unit pixel region PX having one photodiode region PD and four transistors TX, RX, DX and SX, but the image sensor according to the present disclosure is not limited thereto. For example, the reset transistor RX, the drive transistor DX or the selection transistor SX may be shared by adjacent pixel regions PX. Accordingly, integration of the image sensor may be improved.

Description of operation of the image sensor with reference to FIG. 1 is as follows. First, charges remaining in the floating diffusion region FD are discharged by applying the power voltage VDD to a drain of the reset transistor RX and a drain of the drive transistor DX, and turning on the reset transistor RX in a state in which light is blocked. Thereafter, when the reset transistor RX is turned off, and light from the outside is incident on the photodiode region PD, an electron-hole pair is generated in the photodiode region PD. The hole moves to and is accumulated in a P-type impurity region of the photodiode region PD, and the electron moves to and is accumulated in an N-type impurity region. When the transfer transistor TX is turned on, the charge such as the electron and the hole is transferred to and accumulated in the floating diffusion region FD. A gate bias of the drive transistor DX changes in proportion to an amount of the accumulated charge to bring about a change of a source electric potential of the drive transistor DX. In this case, when the selection transistor SX is turned on, a signal caused by the charge is read by a column line.

A wiring line may be electrically connected to at least one of the transfer transistor TX, the reset transistor RX, or the selection transistor SX. The wiring line may be constituted so as to apply the power voltage VDD to the drain of the reset transistor RX or the drain of the drive transistor DX. The wiring line may include a column line connected to the selection transistor SX.

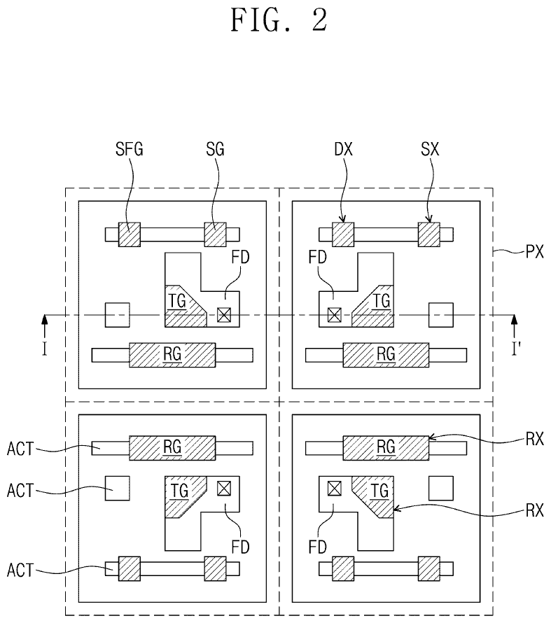

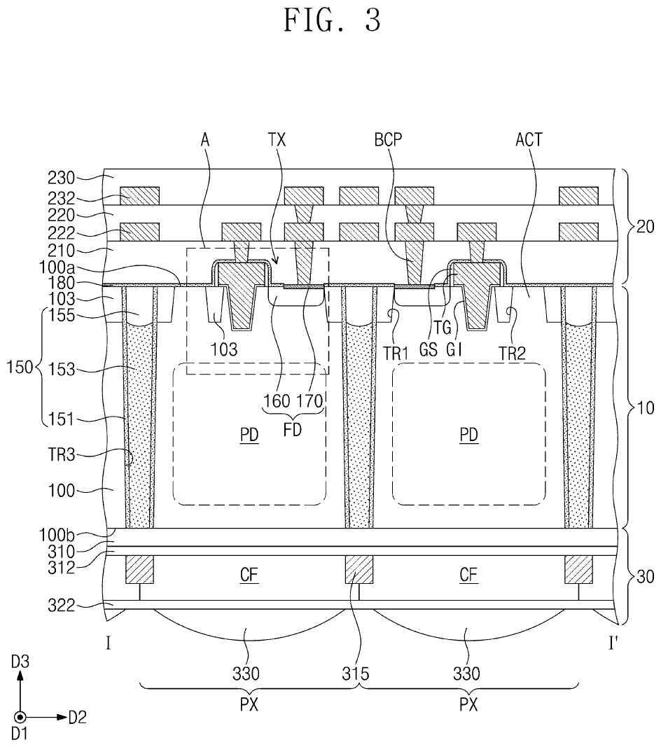

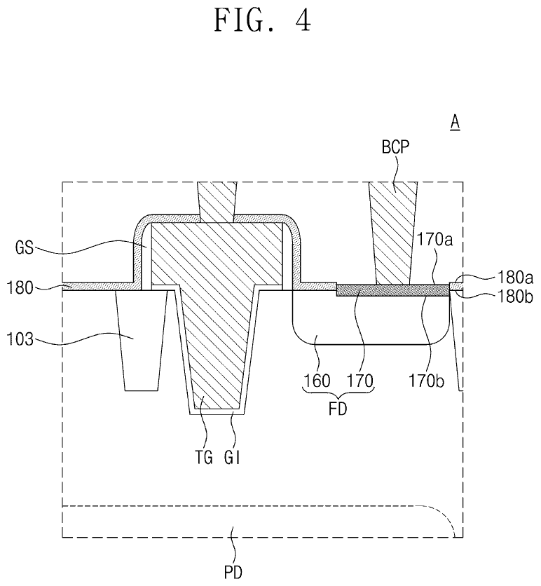

FIG. 2 is a plan view for describing the image sensor according to some implementations of the present disclosure. FIG. 3 is a cross-sectional view for describing the image sensor according to some implementations of the present disclosure. FIG. 4 is an enlarged diagram of portion A of FIG. 3.

Referring to FIGS. 2, 3, and 4, the image sensor according to the present disclosure may include a photodiode layer 10, a wiring layer 20 and a light transmission layer 30. The photodiode layer 10 may be disposed between the wiring layer 20 and the light transmission layer 30.

The photodiode layer 10 may include a substrate 100. The photodiode layer 10 may include a plurality of photodiode regions PD thereinside. The substrate 100 may be a semiconductor substrate (e.g., a silicon substrate, a germanium substrate, a silicon-germanium substrate, a II-VI compound semiconductor substrate, or a III-V compound semiconductor substrate) or a silicon-on-insulator (SOI) substrate. The substrate 100 may have a first surface 100a and a second surface 100b opposed to each other. For example, the first surface 100a of the substrate 100 may be a front surface, and the second surface 100b may be a rear surface. Light may be incident onto the second surface 100b of the substrate 100.

On a plan view, the plurality of photodiode regions PD may be two-dimensionally arranged along a first direction D1 and a second direction D2 parallel to the second surface 100b of the substrate 100. The first direction D1 and the second direction D2 may cross each other. The photodiode region PD may be located between the first surface 100a and the second surface 100b of the substrate 100. The photodiode region PD may be respectively provided in the pixel regions PX of the substrate 100.

The substrate 100 may have a first conductive type, and the photodiode region PD may be a region doped with an impurity having a second conductive type different from the first conductive type. For example, the first conductive type may be a P-type, and the second conductive type may be an N-type. For example, the first conductive type impurity may include at least one of aluminum, boron, indium or gallium. For example, the second conductive type impurity may include at least one of phosphorous, arsenic, bismuth, or antimony. The photodiode region PD may form a PN junction with the substrate 100 to constitute a photodiode.

The photodiode layer 10 may include a shallow element isolation pattern 103. The shallow element isolation pattern 103 may be disposed adjacent to the first surface 100a of the substrate 100. Each of the plurality of pixel regions PX may include active regions ACT defined by the shallow element isolation pattern 103. The shallow element isolation pattern 103 may be disposed in a first trench TR1 and a second trench TR2 recessed from the first surface 100a of the substrate 100. For example, the shallow element isolation pattern 103 may include at least one of silicon oxide, silicon nitride or silicon oxynitride.

The photodiode layer 10 may include a deep element isolation pattern 150. The deep element isolation pattern 150 may be disposed in the substrate 100 between the pixel regions PX. The deep element isolation pattern 150 may at least partially penetrate the substrate 100. The deep element isolation pattern 150 may penetrate the shallow element isolation pattern 103 to extend into the substrate 100. For another example, the deep element isolation pattern 150 and the shallow element isolation pattern 103 may not be distinguished from each other, and may be integrally formed. In this case, a maximum width in the second direction D2 of the deep element isolation pattern 150 may be a sum of a width in the second direction D2 of the shallow element isolation pattern 103 and a width in the second direction D2 of the deep element isolation pattern 150.

The deep element isolation pattern 150 may be disposed in a third trench TR3. The third trench TR3 may penetrate the shallow element isolation pattern 103, and may extend toward the second surface 100b of the substrate 100. A width of an upper portion of the third trench TR3 may be smaller than a width of a bottom surface of the first trench TR1. In the present specification, a width may mean a distance measured in a direction parallel to the second surface 100b of the substrate 100, and for example, may mean a distance measured in the second direction D2. On a plan view, the deep element isolation pattern 150 may have a structure of a lattice surrounding each of the plurality of pixel regions PX. According to some implementations, the deep element isolation pattern 150 may extend from the first surface 100a of the substrate 100 toward the second surface 100b of the substrate 100, and a bottom surface of the deep element isolation pattern 150 may be substantially coplanar with the second surface 100b of the substrate 100. For example, the deep element isolation pattern 150 may include an insulating material having a lower refractive index than the substrate 100.

The deep element isolation pattern 150 may include an isolation pattern 151, a semiconductor pattern 153 and an insulating pattern 155. The isolation pattern 151 may at least partially penetrate the substrate 100. The isolation pattern 151 may be interposed between the pixel region PX and the semiconductor pattern 153. The isolation pattern 151 may be interposed between the substrate 100 and a sidewall of the semiconductor pattern 153, and between the shallow element isolation pattern 103 and the insulating pattern 155. The isolation pattern 151 may extend from a side surface of the semiconductor pattern 153 onto a side surface of the insulating pattern 155. The isolation pattern 151 may at least partially fill the third trench TR3. The isolation pattern 151 may cover an inner sidewall of the third trench TR3. The isolation pattern 151 may expose a bottom surface of the third trench TR3. On a plan view, the isolation pattern 151 may surround each of the pixel regions PX. For example, the isolation pattern 151 may include at least one of oxide, nitride, metal oxide or metal nitride.

The semiconductor pattern 153 may at least partially penetrate the substrate 100. The semiconductor pattern 153 may be interposed between the plurality of pixel regions PX. The semiconductor pattern 153 may fill a lower portion of the third trench TR3. The semiconductor pattern 153 may cover a bottom surface of the third trench TR3. The semiconductor pattern 153 may cover an inner sidewall of the isolation pattern 151, and may be in contact with the isolation pattern 151. An upper surface of the semiconductor pattern 153 may be located at a lower level than the first surface 100a of the substrate 100. In the present specification, a level may mean a height from the second surface 100b of the substrate 100. The bottom surface of the semiconductor pattern 153 may correspond to a bottom surface of the deep element isolation pattern 150, and may be substantially coplanar with the second surface 100b of the substrate 100. The semiconductor pattern 153 may include a conductive material, and may include, for example, a semiconductor material doped with an impurity. The impurity may have a P type or N type conductive type. For example, the semiconductor pattern 153 may include doped polysilicon.

The insulating pattern 155 may be disposed on the semiconductor pattern 153. The insulating pattern 155 may be disposed in the shallow element isolation pattern 103 in the first trench TR1. The insulating pattern 155 may penetrate the shallow element isolation pattern 103 in the first trench TR1 to be in contact with the semiconductor pattern 153. The insulating pattern 155 may be spaced apart from the shallow element isolation pattern 103 in the first trench TR1 by the isolation pattern 151. For example, the insulating pattern 155 may include at least one of silicon oxide, silicon nitride or silicon oxynitride.

The transfer transistor TX and the logic transistors RX, SX and DX described with reference to FIG. 1 above may be disposed on the first surface 100a of the substrate 100. Each of the transistors TX, RX, DX and SX may be disposed on the corresponding active regions ACT of each pixel region PX. Alternatively, some of the transistors TX, RX, DX and SX, for example, the reset transistor RX, the selection transistor SX and the drive transistor DX may be disposed on a separate substrate, not on the substrate 100. Hereinafter, in order to simplify description, it is described that the transistors TX, RX, DX and SX are disposed on the substrate 100 to constitute the pixel regions PX, but it is not excluded that some transistors that constitute the pixel region PX are provided on a separate substrate.

The transfer transistor TX may include a gate electrode TG, the reset transistor RX may include a reset gate electrode RG, and the floating diffusion region FD on a corresponding active region ACT. The gate electrode TG may be disposed on a corresponding photodiode region PD. The gate electrode TG may be disposed adjacent to the shallow element isolation pattern 103 in the second trench TR2. A lower portion of the gate electrode TG may be extended into the substrate 100, and an upper portion of the gate electrode TG may be disposed on the first surface 100a of the substrate 100. A lower surface of the gate electrode TG may be disposed in the substrate 100. A gate dielectric layer GI may be interposed between the gate electrode TG and the substrate 100. The gate dielectric layer GI may include silicon oxide, or a high dielectric material having a greater dielectric constant than silicon oxide. A gate spacer GS may be provided on a sidewall of the upper portion of the gate electrode TG. The gate spacer GS may include at least one of silicon oxide, silicon nitride or silicon oxynitride.

The floating diffusion region FD may be disposed on one side of the gate electrode TG, and may be disposed in a corresponding active region ACT. The floating diffusion region FD may be a region doped with an impurity (for example, an N type impurity) having a second conductive type different from the first conductive type of the substrate 100.

Each of the floating diffusion regions FD may include an impurity region 160 and a doping pad 170. The impurity region 160 may be disposed adjacent to the first surface 100a of the substrate 100. The impurity region 160 may be disposed adjacent to the doping pad 170. The impurity region 160 may surround a lower portion of the doping pad 170. For example, the impurity region 160 may be a region doped with the second conductive type impurity (for example, an N type impurity). For example, the impurity region 160 may be a region doped with at least one impurity of phosphorous (P) or arsenic (As). For example, the impurity region 160 may be a region doped with an impurity at a low concentration.

The doping pad 170 may be provided in a corresponding pixel regions PX, and may be provided on a corresponding photodiode region PD. The doping pad 170 may be disposed adjacent to the first surface 100a of the substrate 100. The doping pad 170 may be horizontally spaced apart from a lower portion of the gate electrode TG extended into the substrate 100, and additionally may be vertically spaced apart from the lower portion of the gate electrode TG. The doping pad 170 may be horizontally spaced apart from the deep element isolation pattern 150, and may not vertically overlap the deep element isolation pattern 150. The doping pad 170 may be exposed onto the first surface 100a of the substrate 100. An upper surface 170a of the doping pad 170 may be located at a higher level than an upper surface of the impurity region 160. For example, the doping pad 170 may include at least one of epitaxial silicon doped with the second conductive type impurity (for example, an N type impurity) or polysilicon doped with the second conductive type impurity (for example, an N type impurity). For example, the doping pad 170 may include the epitaxial silicon doped with an N type impurity. The impurity with which the doping pad 170 is doped may include, for example, at least one of phosphorous (P) or arsenic (As). The doping pad 170 may include a highly doped impurity. For example, the doping pad 170 may have a greater impurity concentration than the impurity region 160.

According to some implementations, the upper surface 170a of the doping pad 170 may be located at a higher level than the first surface 100a of the substrate 100. A lower surface 170b of the doping pad 170 may be located at a lower level than the first surface 100a of the substrate 100. A portion of one sidewall of the doping pad 170 may be in direct contact with the shallow element isolation pattern 103 adjacent thereto. The upper surface 170a of the doping pad 170 may be located at a lower level than an upper surface 180a of an etch stop layer 180 (that is, the upper surface 180a of the etch stop layer 180 on the impurity region 160) to be described later. The lower surface 170b of the doping pad 170 may be located at a lower level than a lower surface 180b of the etch stop layer 180, but an implementation of the present disclosure is not limited thereto. According to another implementation, the upper surface 170a of the doping pad 170 may be substantially coplanar with the upper surface 180a of the etch stop layer 180 on the impurity region 160, and the lower surface 170b of the doping pad 170 may be substantially coplanar with the lower surface 180b of the etch stop layer 180.

The floating diffusion region FD may include the doping pad 170 doped with an impurity at a high concentration, and the doping pad 170 may be horizontally and vertically spaced apart from a lower portion of the gate electrode TG extended into the substrate 100. Since horizontal and vertical distances between the gate electrode TG and the doping pad 170 increase, a gate-induced drain leakage (GIDL) phenomenon generated between the gate electrode TG and the doping pad 170 (that is, the floating diffusion region FD) may be prevented.

The etch stop layer 180 may be provided on the first surface 100a of the substrate 100. The etch stop layer 180 may be interposed between the first surface 100a of the substrate 100 and a first interlayer insulating layer 210 to be described later. The etch stop layer 180 may cover the first surface 100a of the substrate 100. The etch stop layer 180 may cover the transistors TX, RX, DX and SX. The etch stop layer 180 may cover the gate electrode TG and the gate spacer GS. The etch stop layer 180 may not cover the doping pad 170, and the doping pad 170 may be exposed by the etch stop layer 180. The etch stop layer 180 may include at least one of silicon oxide, silicon nitride, silicon oxynitride or silicon carbonitride.

The wiring layer 20 may be disposed on the first surface 100a of the substrate 100. The wiring layer 20 may include the first interlayer insulating layer 210, a second interlayer insulating layer 220 and a third interlayer insulating layer 230 sequentially stacked on the first surface 100a of the substrate 100. The wiring layer 20 may further include contact plugs BCP in the first interlayer insulating layer 210, first wiring patterns 222 in the second interlayer insulating layer 220 and second wiring patterns 232 in the third interlayer insulating layer 230. The first interlayer insulating layer 210 may be disposed on the first surface 100a of the substrate 100 to cover the transistors TX, RX, DX and SX and the doping pad 170, and some of the contact plugs BCP may be connected to terminals of the transistors TX, RX, DX and SX. Some of the contact plugs BCP may be connected to the floating diffusion region FD, and may be in direct contact with the doping pad 170. The contact plugs BCP may be connected to corresponding first wiring patterns 222 among the first wiring patterns 222, and the first wiring patterns 222 may be connected to corresponding second wiring patterns 232 among the second wiring patterns 232. The first and second wiring patterns 222 and 232 may be electrically connected to the transistors TX, RX, DX and SX through the contact plugs BCP. Each of the first to third interlayer insulating layers 210, 220 and 230 may include an insulating material, and the contact plugs BCP, the first wiring patterns 222 and the second wiring patterns 232 may include a conductive material.

The light transmission layer 30 may be disposed on the second surface 100b of the substrate 100. The light transmission layer 30 may include a plurality of color filters CF and a plurality of micro-lenses 330. The light transmission layer 30 may collect and filter light incident from the outside, and the light may be provided to the photodiode layer 10.

The micro-lenses 330 may be provided on the second surface 100b of the substrate 100. Each of the micro-lenses 330 may be disposed so as to vertically (for example, in a third direction D3) overlap the photodiode region PD of a corresponding pixel region PX. The micro-lenses 330 may have a convex shape so as to collect light incident onto the pixel regions PX.

The color filters CF may be disposed between the second surface 100b of the substrate 100 and the micro-lenses 330. Each of the color filters CF may be disposed so as to vertically (for example, in the third direction D3) overlap the photodiode region PD of a corresponding pixel region PX. The color filters CF may include a red, green or blue color filter according to a unit pixel. The color filters CF may be two-dimensionally arranged, and may also include a yellow filter, a magenta filter or a cyan filter.

An anti-reflective layer 310 may be disposed on the second surface 100b of the substrate 100. The anti-reflective layer 310 may be interposed between the second surface 100b of the substrate 100 and the color filters CF. The anti-reflective layer 310 may conformally cover the second surface 100b of the substrate 100. The anti-reflective layer 310 may prevent reflection of light such that the light incident onto the second surface 100b of the substrate 100 smoothly reach the photodiode region PD. For example, the anti-reflective layer 310 may include at least one of silicon oxide, silicon nitride, silicon oxynitride or a high dielectric material (for example, hafnium oxide or aluminum oxide).

A first passivation layer 312 may be interposed between the anti-reflective layer 310 and the color filters CF. A second passivation layer 322 may be interposed between the color filters CF and the micro-lenses 330. The first passivation layer 312 may conformally cover the anti-reflective layer 310. For example, the first passivation layer 312 may include at least one of metal oxide or nitride. For example, the metal oxide may include aluminum oxide, and the nitride may include silicon nitride.

A grid pattern 315 may be provided between the pixel regions PX. The grid pattern 315 may be interposed between the first passivation layer 312 and the color filters CF. The grid pattern 315 may be disposed so as to vertically overlap the deep element isolation pattern 150 in some regions, but may not overlap an element isolation portion 13 in consideration of an incident angle in other regions. On a plan view, the grid pattern 315 may have a lattice shape. The grid pattern 315 may guide light such that the light incident onto the second surface 100b of the substrate 100 may be incident into the photodiode region PD. The grid pattern 315 may include at least one of a metal material or a low refractive index (LRI) material. For example, the metal material may include at least one of tungsten or titanium. For example, the low refractive index (LRI) material may include at least one of silicon oxide or a material having a lower refractive index than the color filters CF.

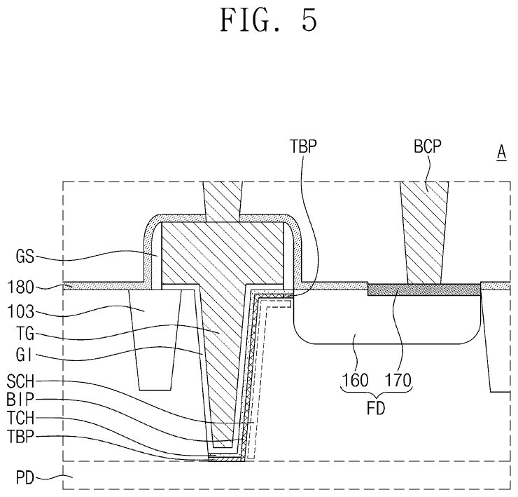

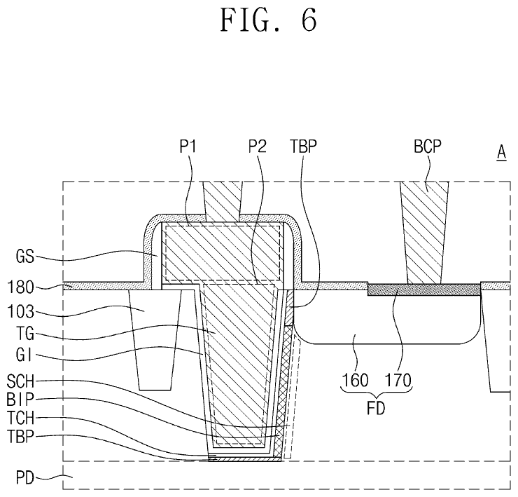

FIGS. 5 and 6 are cross-sectional views for describing the image sensor according to some implementations of the present disclosure, and correspond to a cross-section taken along portion A of FIG. 3. In order to simplify description, a difference from the image sensor described with reference to FIGS. 1 to 4 will be mainly described.

Referring to FIG. 5, the transfer transistor TX may include the gate electrode TG and the floating diffusion region FD on a corresponding active region ACT. The gate electrode TG may be disposed on a corresponding photodiode region PD, and may be disposed adjacent to the shallow element isolation pattern 103 in the second trench TR2. The lower portion of the gate electrode TG may be extended into the substrate 100, and may extend so as to be adjacent to an upper portion of the photodiode region PD. The gate dielectric layer GI may be interposed between the gate electrode TG and the substrate 100. The floating diffusion region FD may be disposed on the photodiode region PD, and may be disposed on one side of the gate electrode TG.

A channel region of the transfer transistor TX may be provided between the substrate 100 and the gate dielectric layer GI. The channel region may mean a moving path of a charge that moves from the photodiode region PD to the floating diffusion region FD. The channel region may include a first channel region extending from a lowermost surface of the gate dielectric layer GI to one side of the floating diffusion region FD, and a second channel region under the first channel region. That is, the channel region of the transfer transistor TX may have a dual channel structure.

Specifically, the first channel region may include a two-dimensional channel layer TCH provided under the gate dielectric layer GI. Since the two-dimensional channel layer TCH extends from the lowermost surface of the gate dielectric layer GI through one side surface of the gate dielectric layer GI under the first surface 100a of the substrate 100, the two-dimensional channel layer TCH may have a stepped structure on a cross-sectional view.

A two-dimensional material that constitutes the two-dimensional channel layer TCH may include a metal chalcogenide-based material having a two-dimensional crystal structure. The two-dimensional material that constitutes the two-dimensional channel layer TCH may include a transition metal dichalcogenide (TMD) material. The TMD material may be expressed as MX₂, in which M is transition metal, and X is a chalcogen element. The M may be Mo, W, Nb, V, Ta, Ti, Zr, Hf, Tc, Re, or the like, and the X may be S, Se, or Te. For specific example, the TMD material may be WSe₂, WTe₂, WS₂, MoSe₂, MoTe₂, MoS₂, ZrS₂, ZrSe₂, HfS₂, HfSe₂, NbSe₂, ReSe₂, or the like. Preferably, the TMD material may include at least one of MoS₂, MoSe₂, MoTe₂, WS₂, WSe₂, or WTe₂. However, the TMD materials proposed above are exemplary, and other TMD materials may be further present.

The second channel region may be provided under the first channel region, and may extend from an upper portion of the photodiode region PD onto the one side of the floating diffusion region FD. The second channel region may include a silicon-based silicon channel layer SCH as a charge moving path in the substrate 100. The silicon channel layer SCH may extend along a two-dimensional insulating layer BIP to be described later to have a structure with bends on a cross-sectional view. That is, the silicon channel layer SCH may have a bent structure. In some implementations, as illustrated in FIG. 5, the silicon channel layer SCH can have (i) a first portion extending along a vertical direction or at a titled angle relative to the vertical direction, and (ii) a second portion extending horizontally. The second portion of the silicon channel layer SCH is connected to an upper end of the first portion of the silicon channel layer SCH. The first portion and the second portion can form a bent structure.

Since the channel region of the transfer transistor TX according to an implementation of the present disclosure has a dual channel structure of the two-dimensional channel layer TCH and the silicon channel layer SCH, a mobility of a charge that moves to the floating diffusion region FD and is accumulated may increase. In addition, since the two-dimensional channel layer TCH has a two-dimensional crystal structure, a charge trap phenomenon caused by a dangling bond may be prevented. Accordingly, the image sensor with improved electrical characteristics may be provided.

A two-dimensional buffer layer TBP may be provided between the two-dimensional channel layer TCH and the photodiode region PD. Specifically, the two-dimensional buffer layer TBP may be disposed between a portion of the two-dimensional channel layer TCH adjacent to a lowermost surface of the gate electrode TG and the photodiode region PD, and between a portion of the two-dimensional channel layer TCH adjacent to one side of the floating diffusion region FD and the silicon channel layer SCH. A two-dimensional material that constitutes the two-dimensional buffer layer TBP may include a metal chalcogenide-based material having a two-dimensional crystal structure. The two-dimensional material that constitutes the two-dimensional buffer layer TBP may include a transition metal dichalcogenide (TMD) material. For example, the two-dimensional buffer layer TBP may include one selected from the group consisting of WSe₂, WTe₂, WS₂, MoSe₂, MoTe₂, MoS₂, ZrS₂, ZrSe₂, HfS₂, HfSe₂, NbSe₂, and ReSe₂. In addition or alternatively, the two-dimensional buffer layer TBP may include graphene, black phosphorous, or titanium carbide.

Since the two-dimensional buffer layer TBP is provided under the first channel region adjacent to the photodiode region PD and the floating diffusion region FD, interface resistance may be reduced, and thus interface bonding of the two-dimensional channel layer TCH and the silicon-based substrate 100 may be improved. In addition, since the two-dimensional buffer layer TBP reduces the interface resistance, the mobility of the charge may be further improved.

The two-dimensional insulating layer BIP may be disposed between the two-dimensional channel layer TCH and the silicon channel layer SCH. Specifically, the two-dimensional buffer layer TBP, the two-dimensional insulating layer BIP and the two-dimensional buffer layer TBP described above may be sequentially disposed under the two-dimensional channel layer TCH, and may be provided. That is, the two-dimensional buffer layer TBP and the two-dimensional insulating layer BIP may be connected to each other to extend along a lower surface of the two-dimensional channel layer TCH and to be formed. The two-dimensional insulating layer BIP may have a two-dimensional crystal structure similar to the two-dimensional channel layer TCH and the two-dimensional buffer layer TBP described above. For example, the two-dimensional insulating layer BIP may include hexagonal boron nitride (h-BN).

The two-dimensional insulating layer BIP may reduce the interface resistance between the substrate 100 and the two-dimensional channel layer TCH, and thus the interface bonding between the two-dimensional insulating layer BIP and the substrate 100, and between the two-dimensional insulating layer BIP and the two-dimensional channel layer TCH may be improved. The two-dimensional insulating layer BIP may prevent the charge trap phenomenon caused by the dangling bond.

Referring to FIG. 6, the transfer transistor TX may include the floating diffusion region FD and the gate electrode TG on a corresponding active region ACT. The gate electrode TG may be disposed on a corresponding photodiode region PD, and may be disposed adjacent to the shallow element isolation pattern 103 in the second trench TR2. A first part P1 of the gate electrode TG may be disposed on the first surface 100a of the substrate 100. The first part P1 may correspond to an upper portion of the gate electrode TG described above. A second part P2 of the gate electrode TG may be extended into the substrate 100, and may extend to the photodiode region PD. The second part P2 may correspond to a lower portion of the gate electrode TG described above.

The second part P2 may be disposed adjacent to the floating diffusion region FD, and thus the first part P1 and the second part P2 may have a misaligned shape. Specifically, the misaligned shape may mean that the first part P1 and the second part P2 vertically overlap each other, but a central line of the first part P1 and a central line of the second part P2 are not identical to each other. Since the second part P2 is adjacent to the floating diffusion region FD, the channel region of the transfer transistor TX may be formed so as to have a short length. That is, since a path of a charge moving from the photodiode region PD to the floating diffusion region FD is short, an effect identical to improvement of the charge mobility may be obtained.

The two-dimensional buffer layer TBP may be interposed between one side surface of the floating diffusion region FD and one side surface of the two-dimensional channel layer TCH included in the first channel region. The two-dimensional insulating layer BIP connected to the two-dimensional buffer layer TBP may be interposed between the two-dimensional channel layer TCH and the silicon channel layer SCH. The silicon channel layer SCH may have a short channel length compared to the silicon channel layer SCH according to an implementation of FIG. 5.

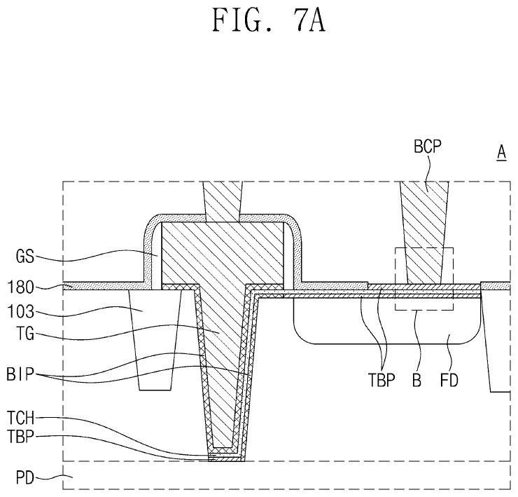

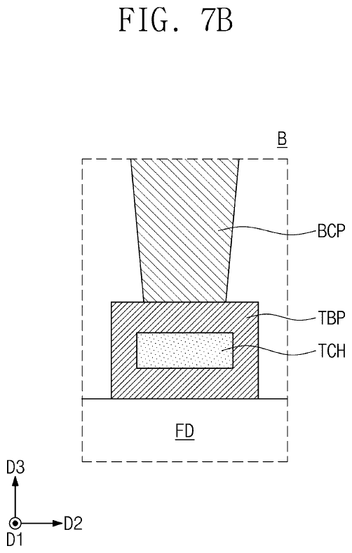

FIGS. 7A and 7B are cross-sectional views for describing the image sensor according to some implementations of the present disclosure, and FIG. 7A corresponds to a cross-section taken along portion A of FIG. 3. FIG. 7B is an enlarged diagram of portion B of FIG. 7A, and is a cross-sectional view taken along a direction crossing line I-I′ of FIG. 2. In order to simplify description, a difference from the image sensor described with reference to FIGS. 1 to 6 will be mainly described.

Referring to FIG. 7A, a channel region of the transfer transistor TX may be provided between the substrate 100 and the two-dimensional insulating layer BIP. The channel region may mean a moving path of a charge moving from the photodiode region PD to the floating diffusion region FD. The channel region may include a first channel region extending from a lowermost surface of the two-dimensional insulating layer BIP to an upper surface of the floating diffusion region FD, and a second channel region under the first channel region. That is, a channel region of the transfer transistor TX may have a dual channel structure.

The two-dimensional insulating layer BIP may be interposed between the first channel region and the gate electrode TG. The two-dimensional insulating layer BIP may include a high dielectric material having a greater dielectric constant than silicon oxide. Since the two-dimensional insulating layer BIP has a two-dimensional crystalline structure, interface bonding between the two-dimensional channel layer TCH may be improved. The two-dimensional insulating layer BIP provided under the gate electrode TG may perform the same role as the gate dielectric layer GI according to other implementations described above.

Specifically, the first channel region may include the two-dimensional channel layer TCH provided under the two-dimensional insulating layer BIP. A two-dimensional material that constitutes the two-dimensional channel layer TCH may include a metal chalcogenide-based material having a two-dimensional crystal structure. The two-dimensional material that constitutes the two-dimensional channel layer TCH may include a transition metal dichalcogenide (TMD) material. The two-dimensional channel layer TCH may extend from a lowermost surface of the two-dimensional insulating layer BIP through one side surface of the two-dimensional insulating layer BIP onto an upper surface of the floating diffusion region FD. The two-dimensional channel layer TCH may extend to the shallow element isolation pattern 103 disposed on one side of the floating diffusion region FD.

The two-dimensional insulating layer BIP and the two-dimensional buffer layer TBP provided under the two-dimensional channel layer TCH may be formed so as to be connected to each other. Specifically, the two-dimensional buffer layer TBP may extend between the two-dimensional channel layer TCH and a silicon channel layer onto the floating diffusion region FD. In this case, the two-dimensional buffer layer TBP may extend to the shallow element isolation pattern 103 located on the other side of the floating diffusion region FD. The two-dimensional insulating layer BIP may be interposed between the two-dimensional channel layer TCH and the substrate 100.

The two-dimensional channel layer TCH and the two-dimensional buffer layer TBP may extend from the photodiode region PD onto the floating diffusion region FD to be formed so as to prevent, on the whole, a charge trap phenomenon generated during an operation of the transfer transistor TX.

Referring to FIG. 7B, FIG. 7B is an enlarged diagram of portion B of FIG. 7A, and is a cross-sectional view taken along a direction crossing line I-I′ of FIG. 2. In other words, FIG. 7B is a diagram illustrating a structure between the two-dimensional buffer layer TBP and the contact plug BCP extending onto the floating diffusion region FD.

Since the contact plug BCP capable of being connected to not only the floating diffusion region FD but also the two-dimensional channel layer TCH is needed due to the dual channel structure of the transfer transistor TX, the two-dimensional buffer layer TBP surrounding the two-dimensional channel layer TCH may be provided. Specifically, the two-dimensional buffer layer TBP may improve the interface bonding between the contact plug BCP and the two-dimensional channel layer TCH, and the interface bonding between the two-dimensional channel layer TCH and the floating diffusion region FD may be improved. The floating diffusion region FD and the contact plug BCP may be directly connected to each other due to a structure in which the two-dimensional buffer layer TBP surrounds the two-dimensional channel layer TCH. In some implementations, as illustrated in FIG. 7B, the two-dimensional buffer layer TBP surrounds the two-dimensional channel layer TCH and extends in a direction parallel to the upper surface of the floating diffusion region FD. The direction parallel to the upper surface of the floating diffusion region FD can be the direction D1 of FIG. 7B. For example, the two-dimensional buffer layer TBP can extend along D1 direction and surround the two-dimensional channel layer TCH in D2 and D3 directions.

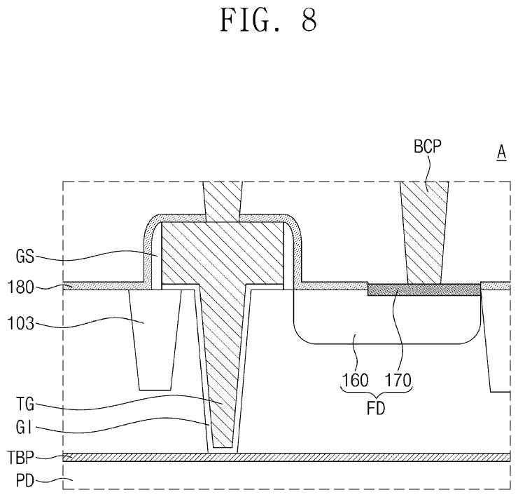

FIG. 8 is a cross-sectional view for describing the image sensor according to some implementations of the present disclosure, and corresponds to a cross-section taken along portion A of FIG. 3. In order to simplify description, a difference from the image sensor described with reference to FIGS. 1 to 7B will be mainly described.

Referring to FIG. 8, the transfer transistor TX may use a silicon-based channel region in the substrate 100 as a charge moving path. In this case, since the charge trap phenomenon occurs due to a dangling bond on the photodiode region PD, the two-dimensional buffer layer TBP capable of reducing interface resistance may be disposed on the photodiode region PD to improve electrical characteristics of the image sensor. The two-dimensional buffer layer TBP on the photodiode region PD may be adjacent to a lowermost surface of the gate dielectric layer GI of the transfer transistor TX. Specifically, a portion of the two-dimensional buffer layer TBP may be in direct contact with the photodiode region PD and the gate dielectric layer GI to be interposed therebetween.

Since the image sensor according to the present disclosure includes a transfer transistor having dual channels through implementation described above, a charge mobility may be improved. In addition, a dual channel structure may reduce a dark noise of the image sensor. In order to prevent a moving charge trap phenomenon, interface resistance of each layer may be reduced, and the two-dimensional buffer layer TBP and the two-dimensional insulating layer BIP that reduce a dangling bond may be appropriately disposed. Accordingly, electrical characteristics and reliability of the image sensor may be improved.

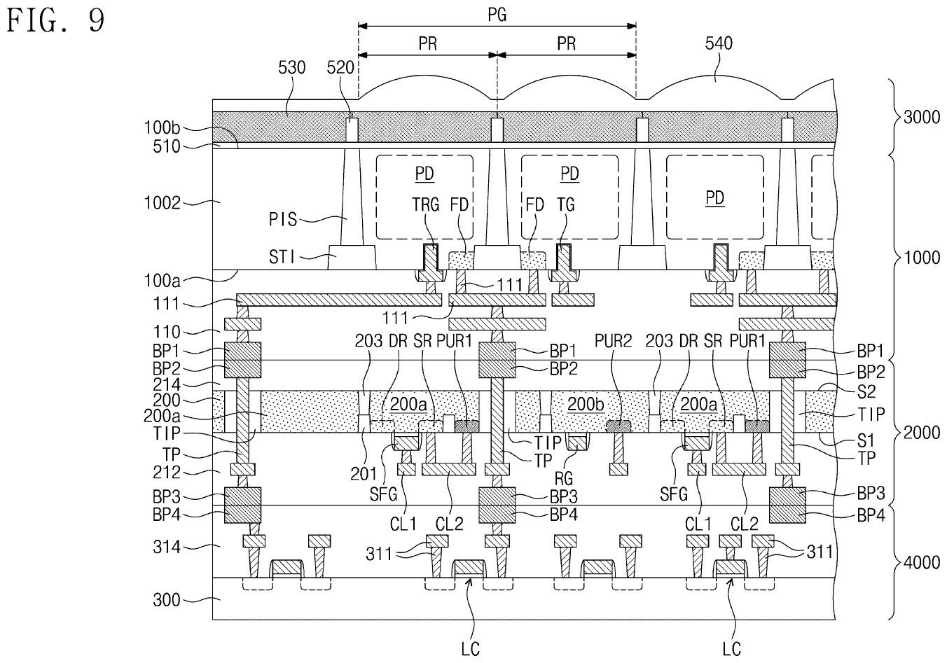

FIG. 9 is a cross-sectional view partially illustrating an image sensor according to some implementations of the present disclosure. Hereinafter, duplicate contents of those described above will be omitted.

Referring to FIG. 9, the image sensor according to implementations of the present disclosure may include a photodiode circuit layer 1000, a pixel circuit layer 2000, a light transmission layer 3000 and a logic circuit layer 4000.

The photodiode circuit layer 1000 may be disposed between the pixel circuit layer 2000 and the light transmission layer 3000 on a vertical view. The photodiode circuit layer 1000 may include a first semiconductor substrate 1002, a pixel isolation structure PIS, a photodiode region PD, a transfer transistor TX, a floating diffusion region FD and first interlayer insulating layers 110. The first semiconductor substrate 1002 may be the same as the substrate 100 (see FIG. 3) described above.

More specifically, the first semiconductor substrate 1002 may have a first surface 100a (or front surface) and a second surface 100b (or rear surface) opposed to each other. The first semiconductor substrate 1002 may be a substrate in which a first conductive type epitaxial layer is formed on a first conductive type (for example, a P type) bulk silicon substrate, or a substrate in which only a P type epitaxial layer remains by removing the bulk silicon substrate on a process of manufacturing the image sensor. Alternatively, the first semiconductor substrate 1002 may be a bulk semiconductor substrate including a first conductive type well.

Each of pixel groups PG may include at least four, eight, or sixteen pixel regions PR. In each pixel group PG, the pixel regions PR may be arranged in a matrix shape along the first direction D1 and the second direction D2 crossing each other. Each of the pixel regions PR may be defined by the pixel isolation structure PIS provided in the first semiconductor substrate 1002.

The pixel isolation structure PIS may be disposed in the first semiconductor substrate 1002, and may vertically extend from the first surface 100a of the first semiconductor substrate 1002 to the second surface 100b. The pixel isolation structure PIS may completely or partially penetrate the first semiconductor substrate 1002. The pixel isolation structure PIS may partially penetrate an element isolation layer STI. The pixel isolation structure PIS may include an isolation insulating pattern and a conductive pattern in the isolation insulating pattern. For another example, the pixel isolation structure PIS may be integrally formed with the element isolation layer STI.

The element isolation layer STI may be disposed adjacent to the first surface 100a of the first semiconductor substrate 1002 in each of the pixel regions PR. The element isolation layer STI may define an active portion in the first surface 100a of the first semiconductor substrate 1002. The element isolation layer STI may be provided in an element isolation trench formed by recessing the first surface 100a of the first semiconductor substrate 1002. The element isolation layer STI may be composed of an insulating material.

The element isolation layer STI may partially overlap the pixel isolation structure PIS. For example, the element isolation layer STI may be disposed on the pixel isolation structure PIS between the pixel regions PR adjacent to each other. The element isolation layer STI may be disposed adjacent to the first surface 100a of the first semiconductor substrate 1002.

The photodiode region PD may be provided in the first semiconductor substrate 1002. The photodiode region PD may generate a photoelectric charge in proportion to an intensity of incident light. The photodiode region PD may be formed by ion-implanting an impurity having a second conductive type opposite to a first conductive type of the first semiconductor substrate 1002 into the first semiconductor substrate 1002. Photodiodes may be formed by junction of the first conductive type first semiconductor substrate 1002 and the second conductive type photodiode region PD.

According to some implementations, the photodiode region PD may have an impurity concentration difference between a region adjacent to the first surface 100a and a region adjacent to the second surface 100b so as to have a potential slope between the first surface 100a and the second surface 100b of the first semiconductor substrate 1002. For example, the photodiode region PD may include a plurality of impurity regions vertically stacked.

The floating diffusion region FD may vertically partially overlap the pixel isolation structure PIS. The floating diffusion region FD may be formed by ion-implanting an impurity having the second conductive type (for example, an N type) in the first semiconductor substrate 1002 having the first conductive type.

The first interlayer insulating layer 110 may cover the gate electrode TG on the first surface 100a of the first semiconductor substrate 1002. For example, the first interlayer insulating layer 110 may include silicon oxide, silicon nitride and/or silicon oxynitride.

A wiring structure 111 connected to the gate electrode TG and the floating diffusion region FD may be disposed in the first interlayer insulating layer 110.

According to an implementation, the photodiode circuit layer 1000 may include first bonding pads BP1 provided in an uppermost metal layer of the photodiode circuit layer 1000. The first bonding pads BP1 may be disposed in an uppermost layer of the first interlayer insulating layer 110.

The first bonding pads BP1 of the photodiode circuit layer 1000 may be connected to the gate electrode TG, the floating diffusion regions FD or ground impurity regions through contact plugs and metal lines.

For example, the first bonding pads BP1 may include at least one of tungsten (W), aluminum (Al), copper (Cu), tungsten nitride (WN), tantalum nitride (TaN), or titanium nitride (TiN).

According to implementations, the pixel circuit layer 2000 may be disposed on the first interlayer insulating layer 110 of the photodiode circuit layer 1000. The pixel circuit layer 2000 may include a pixel circuit of unit pixels. The pixel circuit layer 2000 may be disposed between the photodiode circuit layer 1000 and the logic circuit layer 4000 on a vertical view.

The pixel circuit layer 2000 may include a second semiconductor substrate 200, a penetration plug TP, a penetration insulating pattern TIP and pixel transistors. The pixel transistors may include a source follower transistor, a reset transistor, a dual conversion gain transistor, and a selection transistor.

More specifically, referring to FIG. 9, the second semiconductor substrate 200 may have a first surface S1 and a second surface S2 opposed to each other. The second semiconductor substrate 200 may include a first conductive type semiconductor material, for example, silicon, germanium, silicon-germanium. The second semiconductor substrate 200 may be a bulk substrate or an epitaxial layer.

The second semiconductor substrate 200 may include a first well region 200a having a first conductive type and a second well region 200b having the first conductive type in each pixel group PG. The first well region 200a and the second well region 200b may be isolated by an element isolation pattern 201 and an isolation structure 203.

The element isolation pattern 201 may define first, second and third active portions in the second well region 200b of the second semiconductor substrate 200. The first, second and third active portions may correspond to some portions of the second well region 200b. The element isolation pattern 201 may be disposed adjacent to the first surface S1 of the second semiconductor substrate 200. The element isolation pattern 201 may partially overlap the isolation structure 203. The element isolation pattern 201 may be provided in a trench formed by recessing the first surface of the second semiconductor substrate 200. The element isolation pattern 201 may be composed of an insulating material.

The isolation structure 203 that isolates the first and second well regions 200a and 200b may be disposed in the second semiconductor substrate 200. The isolation structure 203 may surround the first well region 200a on a plan view. The isolation structure 203 may be disposed in the second semiconductor substrate 200, and may vertically extend from the second surface S2 of the second semiconductor substrate 200 to the first surface S1. The isolation structure 203 may completely or partially penetrate the second semiconductor substrate 200. The isolation structure 203 may be composed of an insulating material. According to an implementation, the isolation structure 203 may be in contact with or penetrate the element isolation pattern 201.

The penetration plug TP may penetrate the second semiconductor substrate 200 in each pixel group PG. The penetration plug TP may penetrate the first well region 200a of the second semiconductor substrate 200. The penetration plug TP may electrically connect photodiode circuits of the photodiode circuit layer 1000 and pixel transistors, that is, the source follower transistor of the pixel circuit layer 2000. Specifically, the penetration plug TP may electrically connect the floating diffusion region FD of each pixel group PG and a gate terminal of the source follower transistor. For example, the penetration plug TP may be provided to each of the pixel groups PG, and each pixel group PG may include eight pixel regions PR. That is, the eight pixel regions PR may share one penetration plug TP. For example, the penetration plug TP may include metal such as tungsten, copper, aluminum, or an alloy thereof.

The penetration plug TP may penetrate a portion of a second interlayer insulating layer 212 provided on the first surface S1 of the second semiconductor substrate 200, and a third interlayer insulating layer 214 provided on the second surface S2 of the second semiconductor substrate 200.

A first end portion of the penetration plug TP may be electrically connected to a second bonding pad BP2 provided in the third interlayer insulating layer 214. The second bonding pad BP2 may correspond to the first bonding pad BP1 of the photodiode circuit layer 1000, and may be in direct contact with and be connected to each other.

The penetration insulating pattern TIP may penetrate the first well region 200a of the second semiconductor substrate 200. The penetration insulating pattern TIP may surround a sidewall of the penetration plug TP. That is, the penetration insulating pattern TIP may be disposed between the penetration plug TP and the second semiconductor substrate 200. An upper surface of the penetration insulating pattern TIP may be coplanar with the first surface S1 of the second semiconductor substrate 200, and a lower surface of the penetration insulating pattern TIP may be coplanar with the second surface S2 of the second semiconductor substrate 200. For example, the penetration insulating pattern TIP may include silicon oxide, silicon nitride, and/or silicon oxynitride.

The source follower transistor may be provided on the first well region 200a of the second semiconductor substrate 200. Specifically, the source follower transistor may include a source follower gate electrode SFG disposed on the first surface S1 of the second semiconductor substrate 200, and source and drain regions SR and DR provided in the first well region 200a on both sides of the source follower gate electrode SFG. Here, the source and drain regions SR and DR may be impurity regions doped with impurities having the second conductive type.

A first pick-up impurity region PUR1 may be spaced apart from the source and drain regions SR and DR of the source follower transistor to be provided in the first well region 200a. The first pick-up impurity region PUR1 may be a region doped with an impurity having the first conductive type. For example, the first pick-up impurity region PUR1 may be spaced apart from the source region SR of the source follower transistor by the element isolation pattern 201.

According to implementations, pixel transistors may be provided on the second well region 200b of the second semiconductor substrate 200.

Specifically, the reset transistor and the dual conversion gain transistor may be provided on the first active portion of the second semiconductor substrate 200. The selection transistor may be provided on the second active portion of the second semiconductor substrate 200.

A second pick-up impurity region PUR2 may be disposed in a third active portion of the second semiconductor substrate 200. The second pick-up impurity region PUR2 may be a region doped with an impurity having the first conductive type.

The second interlayer insulating layer 212 may cover the pixel transistors on the first surface S1 of the second semiconductor substrate 200. For example, the second interlayer insulating layer 212 may include first and second insulating layers sequentially stacked. For example, the second interlayer insulating layer 212 may include silicon oxide, silicon nitride and/or silicon oxynitride.

Referring back to FIG. 9, the pixel circuit layer 2000 may include third bonding pads BP3 provided in an uppermost metal layer of the second interlayer insulating layer 212, and second bonding pads BP2 provided in an uppermost metal layer of the third interlayer insulating layer 214. For example, the second and third bonding pads BP2 and BP3 may include at least one of tungsten (W), aluminum (Al), copper (Cu), tungsten nitride (WN), tantalum nitride (TaN), or titanium nitride (TiN).

According to implementations, the second bonding pads BP2 of the pixel circuit layer 2000 may be bonded to the first bonding pads BP1 of the photodiode circuit layer 1000.

The photodiode circuit layer 1000 and the pixel circuit layer 2000 may be electrically connected to each other by directly bonding the first and second bonding pads BP1 and BP2 provided in the uppermost metal layers thereof.

The first bonding pads BP1 of the photodiode circuit layer 1000 and the second bonding pads BP2 of the pixel circuit layer 2000 may be directly electrically connected to each other in a hybrid bonding manner. The hybrid bonding means that two components including the same type material bond at an interface thereof. For example, when the first and second bonding pads BP1 and BP2 are composed of copper (Cu), the first and second bonding pads BP1 and BP2 may be physically and electrically connected to each other by a copper (Cu)-copper (Cu) bonding. In addition, a surface of the first interlayer insulating layer 110 of the photodiode circuit layer 1000 and a surface of the third interlayer insulating layer 214 of the pixel circuit layer 2000 may be bonded by a dielectric-dielectric bonding.

According to implementations, the light transmission layer 3000 may be disposed on the second surface 100b of the first semiconductor substrate 1002. The light transmission layer 3000 may include a planarization insulating layer 510, a lattice structure 520, color filters 530 and micro-lenses 540. The light transmission layer 3000 may collect and filter light incident from the outside to provide the light to the photodiode circuit layer 1000.

Specifically, the planarization insulating layer 510 may cover the second surface 100b of the first semiconductor substrate 1002. The planarization insulating layer 510 may be composed of a transparent insulating material, and may include a plurality of layers. The planarization insulating layer 510 may be composed of an insulating material having a different refractive index from the first semiconductor substrate 1002. The planarization insulating layer 510 may include metal oxide and/or silicon oxide.

The lattice structure 520 may be disposed on the planarization insulating layer 510. The lattice structure 520 may have a lattice shape, on a plan view, similar to the pixel isolation structure PIS. On a plan view, the lattice structure 520 may overlap the pixel isolation structure PIS. That is, the lattice structure 520 may include first parts extending in the first direction D1 and second parts crossing the first parts to extend in the second direction D2. A width of the lattice structure 520 may be substantially the same as or smaller than a minimum width of the pixel isolation structure PIS.

The lattice structure 520 may include a light-blocking pattern and/or a low refraction pattern. For example, the light-blocking pattern may include a metal material such as titanium, tantalum or tungsten. The low refraction pattern may be composed of a material having a lower refractive index than the light-blocking pattern. The low refraction pattern may be composed an organic material, and may have a refractive index of about 1.1 to about 1.3. For example, the lattice structure 520 may be a polymer layer including silica nano-particles.

The color filters 530 may be formed corresponding to each of the pixel regions PR. The color filters 530 may fill a space defined by the lattice structure 520. The color filters 530 may include a red, green, or blue color filter according to a unit pixel, or may include a magenta, cyan, or yellow color filter.

The micro-lenses 540 may be disposed on the color filters 530. The micro-lenses 540 may have a convex shape, and a predetermined radius of curvature. The micro-lenses 540 may be formed of a light transmission resin.

The logic circuit layer 4000 may be bonded to a sensor circuit layer so as to be adjacent to a pixel circuit layer 2022. The logic circuit layer 4000 may include logic circuits, a power circuit, an input-output interface, an image signal processor, and/or the like. That is, the logic circuit layer 4000 may include components, except for the pixel array, in the image sensor of FIG. 2.

Specifically, the logic circuit layer 4000 may include a third semiconductor substrate 300, logic circuits LC, interlayer insulating layers 312 covering the logic circuits LC, and logic lines 311 connected to the logic circuits LC. An uppermost layer of logic interlayer insulating layers 314 may be bonded to the second interlayer insulating layer 212 of the pixel circuit layer 2000.

Fourth bonding pads BP4 may be provided in the uppermost layer of the logic interlayer insulating layers 314, and the fourth bonding pads BP4 may be bonded to the third bonding pads BP3 of the pixel circuit layer 2000.

The photodiode circuit layer 1000 and the pixel circuit layer 2000 may be electrically connected to the logic circuit layer 4000 by directly bonding the third and fourth bonding pads BP3 and BP4. The third bonding pad BP3 and the fourth bonding pads BP4 may be also directly electrically connected to each other in the hybrid bonding manner.

An image sensor according to the present disclosure may improve a mobility of a charge moving from a photodiode region to a floating diffusion region by forming a channel of a transfer transistor as a dual channel structure. One of the dual channels includes a TMD material, and the other of the dual channels includes silicon so that a charge trap phenomenon caused by a dangling bond may be prevented, and thus the image sensor with improved electrical characteristics may be provided.

The image sensor according to the present disclosure may include a buffer layer between the photodiode region and a channel region, and between the floating diffusion region and the channel region, or may replace a gate dielectric layer with a different two-dimensional material, thereby minimizing a noise generated by operating the image sensor. Accordingly, performance of the image sensor may be improved by improving a random noise phenomenon.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An image sensor comprising:
a substrate including a first surface and a second surface opposed to each other, the substrate including a photodiode region;
a gate electrode on the photodiode region, a lower portion of the gate electrode being extended into the substrate, and an upper portion of the gate electrode being disposed on the first surface of the substrate;
a gate dielectric layer between the gate electrode and the substrate;
a floating diffusion region on the photodiode region and on a side of the gate electrode; and
a channel region extending from a lower surface of the gate dielectric layer onto a side of the floating diffusion region,
wherein the channel region includes:
a first channel region under the gate dielectric layer; and
a second channel region under the first channel region, and
wherein the first channel region includes a two-dimensional channel layer that includes a transition-metal dichalcogenide (TMD) material.

2. The image sensor of claim 1, wherein the second channel region comprises a silicon channel layer.

3. The image sensor of claim 2, comprising:
a two-dimensional buffer layer between the two-dimensional channel layer and the photodiode region, and between the two-dimensional channel layer and the silicon channel layer; and
a two-dimensional insulating layer between (i) the two-dimensional channel layer that is on a side of the gate dielectric layer and (ii) the silicon channel layer.

4. The image sensor of claim 3, wherein the two-dimensional buffer layer and the two-dimensional insulating layer are connected to each other to extend along a lower surface of the two-dimensional channel layer.

5. The image sensor of claim 1, wherein the TMD material comprises at least one of WSe₂, WTe₂, WS₂, MoSe₂, MoTe₂, MoS₂, ZrS₂, ZrSe₂, HfS₂, HfSe₂, NbSe₂, or ReSe₂.

6. The image sensor of claim 3, wherein the two-dimensional buffer layer comprises at least one of WSe₂, WTe₂, WS₂, MoSe₂, MoTe₂, MoS₂, ZrS₂, ZrSe₂, HfS₂, HfSe₂, NbSe₂, ReSe₂, graphene, black phosphorous, or titanium carbide.

7. The image sensor of claim 3, wherein the two-dimensional insulating layer comprises hexagonal boron nitride (h-BN).

8. The image sensor of claim 1, wherein the two-dimensional channel layer has a stepped structure.

9. The image sensor of claim 3, wherein the silicon channel layer has a structure with bends along the two-dimensional insulating layer.

10. The image sensor of claim 1, wherein the second channel region comprises a silicon channel layer,
the lower portion of the gate electrode is adjacent to the floating diffusion region, and
the lower portion of the gate electrode and the upper portion of the gate electrode are misaligned with each other.

11. The image sensor of claim 10, comprising a two-dimensional buffer layer between the two-dimensional channel layer and the floating diffusion region.

12. An image sensor comprising:
a substrate including a first surface and a second surface opposed to each other, the substrate including a photodiode region;
a gate electrode on the photodiode region, a lower portion of the gate electrode being extended into the substrate, and an upper portion of the gate electrode being disposed on the first surface of the substrate;
a first two-dimensional insulating layer between the gate electrode and the substrate;
a floating diffusion region on the photodiode region and on a side of the gate electrode;
a two-dimensional channel layer extending from a lowermost surface of the first two-dimensional insulating layer onto an upper surface of the floating diffusion region;
a second two-dimensional insulating layer between the two-dimensional channel layer and the substrate;
a two-dimensional buffer layer provided to an upper portion and a lower portion of the two-dimensional channel layer on the floating diffusion region; and
a contact plug in contact with the two-dimensional buffer layer,
wherein the first and second two-dimensional insulating layers include an insulating material having a two-dimensional crystal structure.

13. The image sensor of claim 12, wherein the insulating material comprises hexagonal boron nitride.

14. The image sensor of claim 12, wherein the two-dimensional channel layer comprises a transition-metal dichalcogenide (TMD) material, and
wherein the TMD material comprises at least one of WSe₂, WTe₂, WS₂, MoSe₂, MoTe₂, MoS₂, ZrS₂, ZrSe₂, HfS₂, HfSe₂, NbSe₂, or ReSe₂.

15. The image sensor of claim 12, wherein the two-dimensional buffer layer surrounds the two-dimensional channel layer and extends in a direction parallel to the upper surface of the floating diffusion region.

16. The image sensor of claim 12, wherein the two-dimensional buffer layer comprises at least one of WSe₂, WTe₂, WS₂, MoSe₂, MoTe₂, MoS₂, ZrS₂, ZrSe₂, HfS₂, HfSe₂, NbSe₂, ReSe₂, graphene, black phosphorous, or titanium carbide.

17. The image sensor of claim 12, wherein the two-dimensional buffer layer is on the photodiode region.

18. An image sensor comprising:
a substrate including a first surface and a second surface opposed to each other, the substrate having a first trench recessed from the first surface of the substrate;
a shallow element isolation pattern in the first trench;
a deep element isolation pattern in the substrate, the deep element isolation pattern defining a pixel region;
a photodiode region in the substrate;
a gate electrode on the photodiode region;
a gate dielectric layer under the gate electrode;
a channel region between the gate dielectric layer and the photodiode region;
a floating diffusion region on the photodiode region and on a side of the gate electrode;
a contact plug on the first surface of the substrate and electrically connected to the floating diffusion region;
a micro-lens on the second surface of the substrate; and
color filters between the substrate and the micro-lens,
wherein the channel region includes:
a first channel region under the gate dielectric layer; and
a second channel region under the first channel region,
wherein the first channel region includes a two-dimensional channel layer that includes a TMD material,
the second channel region includes a silicon channel layer, and
the two-dimensional channel layer has a stepped structure, and the silicon channel layer has a structure with bends.

19. The image sensor of claim 18, comprising:
a two-dimensional buffer layer between the two-dimensional channel layer and the photodiode region, and between the two-dimensional channel layer and the silicon channel layer; and
a two-dimensional insulating layer between (i) the two-dimensional channel layer that is on a side of the gate dielectric layer and (ii) the silicon channel layer.

20. The image sensor of claim 19, wherein the two-dimensional channel layer comprises a transition-metal dichalcogenide (TMD) material,
the TMD material comprises at least one of WSe₂, WTe₂, WS₂, MoSe₂, MoTe₂, MoS₂, ZrS₂, ZrSe₂, HfS₂, HfSe₂, NbSe₂, or ReSe₂,
the two-dimensional buffer layer comprises at least one of WSe₂, WTe₂, WS₂, MoSe₂, MoTe₂, MoS₂, ZrS₂, ZrSe₂, HfS₂, HfSe₂, NbSe₂, ReSe₂, graphene, black phosphorous, or titanium carbide, and
the two-dimensional insulating layer comprises hexagonal boron nitride.
